(19) United States
(12) Patent Application Publication
(10) Pub. No.: US 2003/0003656 A1
(43) Pub. Date: Jan. 2, 2003

(54) Method of manufacturing flash memory device

(75) Inventors: Cha Deok Dong, Ichon-Shi (KR); Jeong Hwan Park, Ichon-Shi (KR)

Correspondence Address: MORGAN LEWIS & BOCKIUS LLP, 1111 PENNSYLVANIA AVENUE NW, WASHINGTON, DC, 20004, US

(73) Assignee: Hynix Semiconductor Inc.

(21) Appl. No.: 10/004,784

(22) Filed: Dec. 7, 2001

(30) Foreign Application Priority Data
Jun. 29, 2001 (KR) 2001-38389

(51) Int. Cl. H01L 21/336

(52) U.S. Cl. 438/257; 438/261; 438/264

(57) ABSTRACT

The present invention relates a method of manufacturing a flash memory device. In case of forming a dielectric film consisting of a lower oxide film, a nitride film and upper oxide film that is formed between a floating gate and a control gate, a nitrification process is performed after the lower oxide film is formed, thus forming a nitrogen layer below the lower oxide film. Then, an annealing process using an oxygen gas is performed to move the nitrogen layer onto the surface of the lower oxide film, thus forming a nitride film. Therefore, the present invention can reduce the effective thickness of the dielectric film.

### BACKGROUND OF THE INVENTION

1. Field of the Invention

The invention relates generally to a method of manufacturing a flash memory device. More particularly, the invention relates to a method of manufacturing a flash memory device capable of reducing the effective thickness of a dielectric film, in a way that a lower oxide film is formed and the dielectric film consisting of the lower oxide film, a nitride film and a upper oxide film is then formed by implementing a nitrification process and oxygen annealing process.

2. Description of the Prior Art

Currently, an ONO film is usually used as a dielectric film of a high-integration flash memory device of over 0.18 μm, which consists of a lower oxide film(SiO₂), a nitride film(Si₃N₄) and a upper oxide film(SiO₂). The ONO film has the effective thickness of about 100 Å. In addition, if the thickness of the ONO film is reduced within the range in which the insulating breakage strength characteristic of a gate oxide film is not degraded, the ONO film can be used for a low voltage device. The gate of the flash memory cell can be effectively controlled by even low voltage.

The ONO film serves as a barrier for preventing loss of electrons into a control ate in the floating gate. In order to perform this barrier, a thermal oxide film is most suitable. As the first polysilicon film used as the floating gate is crystallized and doped in-situ, however, the degree of oxidization in the grain and the grain boundary is different. As such, when the oxidization process is implemented, it is difficult to uniformly exactly control the thickness of a grown oxide film. Therefore, in a basic process today, a high temperature oxide film (HTO) deposited in thickness of about 40 Å by means of chemical vapor deposition(CVD) method using SiH₂Cl₂(DCS) gas, is used as the lower oxide film and the upper oxide film of the ONO film, respectively. A Si₃N₄ film deposited in thickness of about 50˜60 Å by means of LPCVD method is used as the nitride film. Further, in order to stabilize the interface characteristic and remove the trap charges, a steam annealing process of a wet oxidization process is implemented.

As above, it is assumed that the entire thickness of the ONO film is important. As the design rule becomes small, there is a necessity to deposit the ONO film having a small effective rule. As the ONO film consists of three films, however, there is rarely reduction in the thickness and variations in the ratio. Thus, there is a limitation to reduce the thickness. Also, it is difficult to prohibit increase in the leakage current and decrease in the breakdown current.

### SUMMARY OF THE INVENTION

It is therefore an object of the present invention to provide a method of manufacturing a flash memory device capable of reducing the effective thickness of a dielectric film.

Another object of the present invention is to provide a method of manufacturing a flash memory device capable of easily implementing a low voltage flash memory device by reducing the effective thickness of a dielectric film.

In order to accomplish the above object, a method of manufacturing a flash memory device according to the present invention is characterized in that it comprises the steps of sequentially forming a tunnel oxide film and a first polysilicon film on a semiconductor substrate and then etching the first polysilicon film and a given region of the tunnel oxide film; forming a lower oxide film on the entire structure; performing a nitrification process to form a nitrogen layer below the lower oxide film; performing an annealing process using an oxygen gas so that the nitrogen layer is moved on the surface of the lower oxide film, thus forming a nitride film; forming a upper oxide film on the entire surface to form a dielectric film consisting of the lower oxide film, the nitride film and the upper oxide film; sequentially forming a second polysilicon film, a tungsten silicide film and an anti-reflection film on the entire structure; and patterning the anti-reflection film, the tungsten silicide film, the second polysilicon film and the dielectric film to form a control gate, and then patterning the first polysilicon film and the tunnel oxide film to form a floating gate.

The lower oxide film is formed using DCS gas and N₂O or NO gas at the temperature of 810˜850° C. and is also formed in thickness of 35·100 Å at the deposition rate of 4˜10 Å/min.

The nitrification process is performed by introducing N₂O or NO of 1˜20 l into the furnace at the temperature of 810˜850° C. for 10˜20 minutes so that the nitrogen film can have the thickness of 3˜5 Å. The annealing process using the oxygen gas is performed by introducing an oxygen gas of 5˜20 l into the furnace at the temperature of 850˜950° C for 5˜20 minutes.

The upper oxide film is formed using DCS gas and N₂O or NO gas at the temperature of 810˜850° C. and is also formed in thickness of 35˜100 Å at the deposition rate of 4˜10 Å/min.

The second polysilicon film is formed in a double structure of a doped polysilicon film and an undoped polysilicon film, the polysilicon film and the undoped polysilicon film is deposited at the ratio of 4:1˜7:1.

### BRIEF DESCRIPTION OF THE DRAWINGS

The aforementioned aspects and other features of the present invention will be explained in the following description, taken in conjunction with the accompanying drawings, wherein:

FIGS. 1A through 1E are cross-sectional views of a flash memory device, which are sequentially shown in order to explain a method of manufacturing the device according to the present invention;

FIG. 2 is a process chart illustrating the detailed condition for forming a dielectric film of the flash memory device according to the present invention; and

FIGS. 3A and 3B illustrate the concentration distribution of nitrogen after a lower oxide film is nitrified and an oxygen annealing process is performed, according to the present invention.

### DETAILED DESCRIPTION OF PREFERRED EMBODIMENTS

The present invention will be described in detail by way of a preferred embodiment with reference to accompanying drawings, in which like reference numerals are used to identify the same or similar parts.

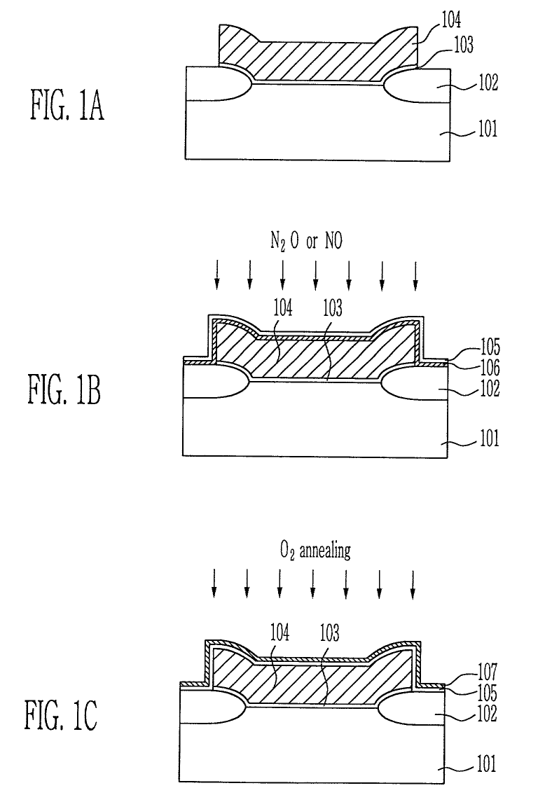

FIGS. 1A through 1E are cross-sectional views of a flash memory device, which are sequentially shown in order to explain a method of manufacturing the device according to the present invention.

Referring now to FIG. 1A, a device isolation film 102 is formed at a given region of a semiconductor substrate 101 to define an active region and a device isolation region. An impurity ion implantation process is performed on the semiconductor substrate 101 of the defined active region to form a well region (not shown). Then, a tunnel oxide film 103 and a first polysilicon film 104 are sequentially formed on the entire structure. The first polysilicon film 104 and a given region of the tunnel oxide film 103 are etched by means of photolithography using the first mask and etching process. The semiconductor substrate 101 is cleaned before the tunnel oxide film 103 is formed. At this time, a mixed solution of HF and SC-1 in the ratio of 50:1 may be used or a mixed solution of BOE and SC-1 in the ratio of 100:1˜300:1 may be used. In addition, the tunnel oxide film 103 is formed by performing wet oxidization process at the temperature of 750˜800° C. and by performing annealing process at the temperature of 900˜910° C. under nitrogen (N₂) atmosphere of 5˜10 l for 20-30 minutes. As above, the interface defect density with semiconductor substrate 101 can be minimized since the tunnel oxide film 103 is formed by wet oxidization process. Meanwhile, the first polysilicon film 104 is formed at the temperature of 550˜620° C. under the pressure of 0.1˜1 Torr using SiH₄ or Si₂H₆ and PH₃ gas. At this time, with the phosphorous (P) concentration of the first polysilicon film 104 being a high concentration of 1.0E20˜3.0E20 atoms/cc, sufficient dopants are supplied in order to give the conductivity through diffusion and activation of phosphorous by means of a subsequent annealing process.

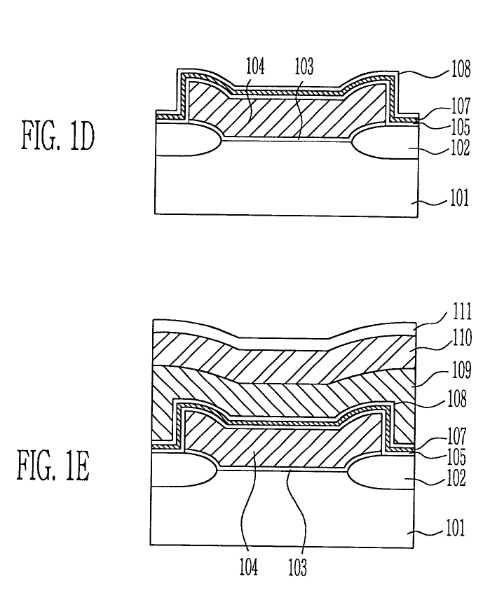

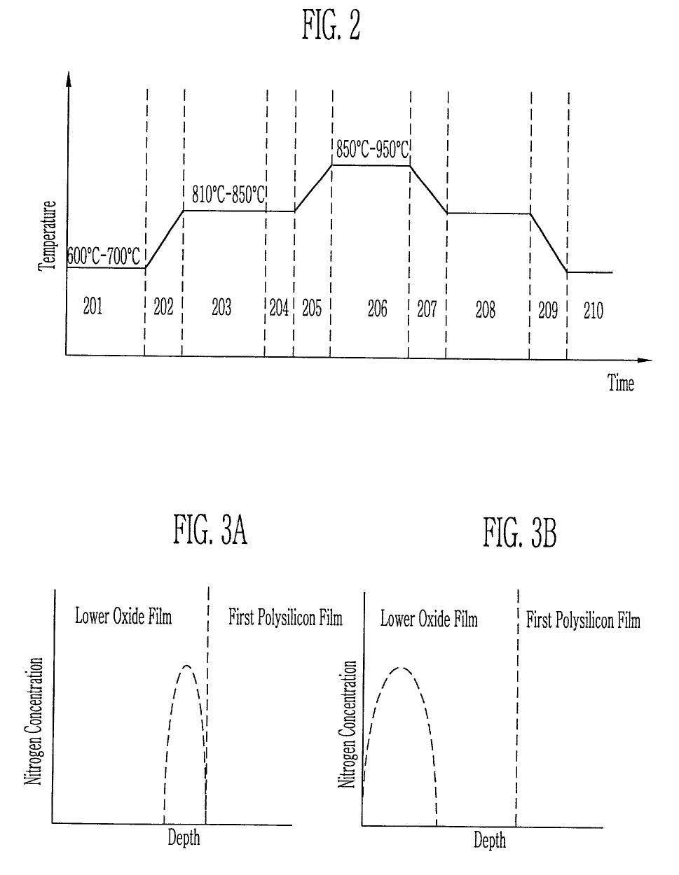

Referring now to FIGS. 1B and 2, the wafer in which the tunnel oxide film 103 and the first polysilicon film 104 are formed is loaded into a reaction furnace in which the temperature of 600˜700° C. and N₂ atmosphere of 10˜20 l are kept (201 in FIG. 2). After the temperature of the furnace is raised at the N₂ atmosphere of 5˜10 l to 810˜850° C.(202 in FIG. 2), a lower oxide film 105 is deposited by means of LPCVD method using DCS and N₂O or NO gas (203 in FIG. 2). At this time, the lower oxide film 105 is deposited in thickness of 35˜100 Å at the deposition rate of 4˜10 Å/min. Also, with the temperature of the furnace kept at 810˜850° C., introduction of DCS is stopped. Nitrification process by which N₂O or NO gas of 1˜20 l is introduced for 10˜20 minutes is then implemented (204 in FIG. 2). At this time, the thickness of the increasing lower oxide film 105 is about 3˜5 Å. The reason is that the nitrogen layer 106 is formed below the lower oxide film 105 as the nitrogen concentration distribution shown in FIG. 3A. In other words, the nitrogen layer 106 is formed in thickness of 3˜5 Å below the lower oxide film 105.

Referring now to FIGS. 1C and 2, after the nitrification process, a nitrogen purge process is implemented to raise the temperature of the furnace to 850˜950° C. under the N₂ atmosphere of 5˜10 l (205 in FIG. 2). After the temperature within the furnace is raised, an annealing process is implemented by introducing an oxygen gas of about 5˜20 l for 5˜20 minutes (206 in FIG. 2). Thus, the surface of the first polysilicon film 104 is oxidized and the nitrogen layer 106 is therefore moved on a upper side of the lower oxide film 105, thus forming a nitride film 107, as shown in FIG. 3B.

By reference to FIGS. 1D and 2, after the temperature within the furnace is decreased to 810˜850° C. under the N₂ atmosphere of 5˜10 (207 in FIG. 2), a upper oxide film 108 is formed in thickness of 35˜100 Å by means of LPCVD method using DCS gas and N₂O or NO gas (208 in FIG. 2). Then, after the temperature within the furnace is decreased to 600˜700° C. (209 in FIG. 2), the wafer in which the ONO dielectric film is formed is unloaded from the furnace (210 in FIG. 2).

Referring now to FIG. 1E, a second polysilicon film 109 and a tungsten silicide film 110 are sequentially formed on the entire structure and an anti-reflection film 111 is then formed. At this time, the second polysilicon film 109 is formed by means of LPCVD method at the temperature of 530˜550° C. under the pressure of 0.1˜1 Torr. Meanwhile, the second polysilicon film 109 may be formed in a double structure of a doped polysilicon film and an undoped polysilicon film. At this time, it is recommended that the deposition ratio of the doped polysilicon film and the undoped polysilicon film is 4:1˜7:1 and the entire thickness is 500˜1000 Å. By doing this, when the tungsten silicide film 110 is deposited, diffusion of fluorine (F) that is solidified/substituted into the dielectric film and that can increase the thickness of the dielectric film can be prevented.

In case of forming the second polysilicon film in a double structure, the second polysilicon film is formed in-situ. The double structure can be formed as follows: the doped polysilicon film is first formed using SiH₄ or Si₂H₆ and PH₃ gas, and the undoped polysilicon film is then formed by introducing only SiH₄ or Si₂H₆ gas with introduction of PH₃ gas being stopped. Also, the tungsten silicide film 109 is formed enough to implement an adequate step coverage at the temperature of 300˜500° C. using the reaction of DCS and WF₆ that have a lower fluorine (F) content, a low post anneal stress and a good adhesive force, and to have the stoichiometric ratio of about 2.0˜2.8 in order to minimize the sheet resistance. Also, the anti-reflection film 111 is formed of an oxidization nitride film or a nitride film. Thereafter, the anti-reflection film 111, the tungsten silicide film 110 and the second polysilicon film 109 are patterned by means of the photolithography process using the second mask to form a control gate. Then, the upper oxide film 108, the nitride film 107, the lower oxide film 105, the first polysilicon film 104 and the tunnel oxide film 103 are etched to form a floating gate. Thus, a stack gate in which the floating gate, the ONO dielectric film and the control gate are stacked is formed. Thereafter, an impurity ion implantation process is performed to form a source and a drain, thus completing a stack gate type flash memory cell.

As can be understood from the above description with the present invention, as the thickness of the ONO film can be reduced, the gate can be effectively controlled and a low voltage flash memory device can be thus easily implemented. Also, it can be expected that the nitride film formed by oxygen annealing process has a low electron capture density compared to an existing ONO film formation process since the nitride film has a low nitrogen concentration file up within the lower oxide film. Due to this, the operating characteristic of the device can be improved. Further, as the dielectric film formation process and the steam anneal process are substituted with a single process, the cost is reduced and the productivity is also improved.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed are:

1. A method of manufacturing a flash memory device, comprising the steps of:
sequentially forming a tunnel oxide film and a first polysilicon film on a semiconductor substrate and then etching said first polysilicon film and a given region of said tunnel oxide film;
forming a lower oxide film on the entire structure;
performing a nitrification process to form a nitrogen layer below said lower oxide film;
performing an annealing process using an oxygen gas so that said nitrogen layer is moved on the surface of said lower oxide film, thus forming a nitride film;
forming a upper oxide film on the entire surface to form a dielectric film consisting of said lower oxide film, said nitride film and said upper oxide film;
sequentially forming a second polysilicon film, a tungsten silicide film and an anti-reflection film on the entire structure; and
patterning said anti-reflection film, said tungsten silicide film, said second polysilicon film and said dielectric film to form a control gate, and then patterning said first polysilicon film and said tunnel oxide film to form a floating gate.

2. The method of manufacturing a flash memory device according to claim 1, wherein said lower oxide film is formed using DCS gas and N₂O or NO gas at the temperature of 810˜850° C.

3. The method of manufacturing a flash memory device according to claim 1, wherein said lower oxide film is formed in thickness of 35˜100 Å at the deposition rate of 4˜10 Å/min.

4. The method of manufacturing a flash memory device according to claim 1, wherein said nitrification process is performed by introducing N₂O or NO of 1˜20 l into the furnace at the temperature of 810˜850° C. for 10˜20 minutes, thus forming a nitrogen layer of 3˜5 Å in thickness in said lower oxide film.

5. The method of manufacturing a flash memory device according to claim 1, wherein said annealing process using the oxygen gas is performed by introducing an oxygen gas of 5˜20 l into the furnace at the temperature of 850˜950° C. for 5˜20 minutes.

6. The method of manufacturing a flash memory device according to claim 1, wherein said upper oxide film is formed using DCS gas and N₂O or NO gas at the temperature of 810˜850° C.

7. The method of manufacturing a flash memory device according to claim 1, wherein said upper oxide film is formed in thickness of 35˜100 521 at the deposition rate of 4˜10 Å/min.

8. The method of manufacturing a flash memory device according to claim 1, wherein said second polysilicon film is formed in a double structure of a doped polysilicon film and an undoped polysilicon film.

9. The method of manufacturing a flash memory device according to claim 8, wherein said polysilicon film and said undoped polysilicon film is deposited at the ratio of 4:1˜7:1.
